(19) United States
(12) Patent Application Publication
(10) Pub. No.: US 2026/0136458 A1
(43) Pub. Date: May 14, 2026

(54) PRINTED CIRCUIT BOARD

(71) Applicant: SAMSUNG ELECTRO-MECHANICS CO., LTD., Suwon-si (KR)

(72) Inventors: Sung Chul Choi, Suwon-si (KR); Jung Soo Kim, Suwon-si (KR)

(73) Assignee: SAMSUNG ELECTRO-MECHANICS CO., LTD., Suwon-si (KR)

(21) Appl. No.: 19/295,272

(22) Filed: Aug. 8, 2025

(30) Foreign Application Priority Data
Nov. 14, 2024 (KR) 10-2024-0162011

(51) Int. Cl. H05K 1/02; H05K 1/11

(52) U.S. Cl. CPC H05K 1/0298; H05K 1/115; H05K 2201/096; H05K 2201/09827

(57) ABSTRACT

A printed circuit board includes a first insulating body, a plurality of wiring layers formed on or within the first insulating body, and a plurality of via layers disposed in the first insulating body and connected to at least one of the wiring layers. An uppermost wiring layer includes an embedded pattern exposed from the upper surface of the insulating body. A protruding pattern is formed on the embedded pattern to provide a protruding pad structure. The embedded pattern has a thickness less than that of wiring patterns in the lower wiring layers, and the combined thickness of the embedded and protruding patterns is substantially equal to the thickness of the lower wiring patterns. This structure enables improved dimensional control and mounting reliability without requiring plasma etching of the insulating body.

### CROSS-REFERENCE TO RELATED APPLICATION(S)

This application claims the benefit of priority to Korean Patent Application No. 10-2024-0162011 filed on Nov. 14, 2024 with the Korean Intellectual Property Office, the disclosure of which is incorporated herein by reference in its entirety.

### TECHNICAL FIELD

The present disclosure relates to a printed circuit board.

Due to implementation of high performance of semiconductor chips such as APs of smartphones, CPUs for servers, and AI accelerators, demand for package substrates including high-density circuits has been growing. Accordingly, bump pitch has been shrinking, and high layer counts and large substrate areas have been increasingly required. In addition, in order to respond to the growing number of input and output terminals, microcircuit implementation technology has become increasingly important.

### SUMMARY

An aspect of the present disclosure is to provide a printed circuit board capable of facilitating formation of a microcircuit, providing a partially protruding pad having guaranteed size uniformity, and improving a reliability issue related to the pad.

A pad may be provided by additionally forming a protruding pattern on an outermost embedded pattern of a coreless substrate. In this case, the outermost embedded pattern may have a relatively small thickness, and thus a pad having desired dimensions may be implemented.

According to an aspect of the present disclosure, there is provided a printed circuit board includes a first insulating body, a plurality of first wiring layers respectively disposed on or in the first insulating body, and a plurality of first via layers respectively disposed in the first insulating body, the plurality of first via layers respectively connected to at least one first wiring layer, among the plurality of first wiring layers. An uppermost first wiring layer, among the plurality of first wiring layers, may include a embedded pattern buried in an upper side of the first insulating body such that at least a portion of an upper surface thereof is exposed from an upper surface of the first insulating body. A protruding pattern may be disposed on the embedded pattern. A thickness of the embedded pattern may be less than a thickness of a wiring pattern included in at least one of remaining first wiring layers excluding the uppermost first wiring layer.

According to another aspect of the present disclosure, there is provided a printed circuit board including a plurality of insulating layers, a plurality of wiring layers respectively disposed on or in the plurality of insulating layers, a plurality of via layers respectively disposed in the plurality of insulating layers, the plurality of via layers respectively connected to at least one insulating layer, among the plurality of insulating layers, and a pattern layer disposed on an outermost wiring layer, among the plurality of wiring layers, the pattern layer in direct contact with the outermost wiring layer. The outermost wiring layer may be buried in an outermost insulating layer, among the plurality of insulating layers, such that one surface thereof is exposed from one surface of the outermost insulating layer. A thickness of the outermost wiring layer may be less than a thickness of each of the remaining wiring layers, among the plurality of wiring layers.

According to example embodiments of the present disclosure, a printed circuit board may facilitate formation of a microcircuit, provide a partially protruding pad having guaranteed size uniformity, and improve a reliability issue related to the pad.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a schematic block diagram of an example electronic device system;

FIG. 2 is a schematic cross-sectional view of an example printed circuit board; and

FIGS. 3 to 5 are schematic process cross-sectional views of an example of manufacturing the printed circuit board of FIG. 2.

### DETAILED DESCRIPTION

Hereinafter, example embodiments of the present disclosure are described with reference to the accompanying drawings. The shapes and sizes of components in the drawings may be exaggerated or reduced for clearer description.

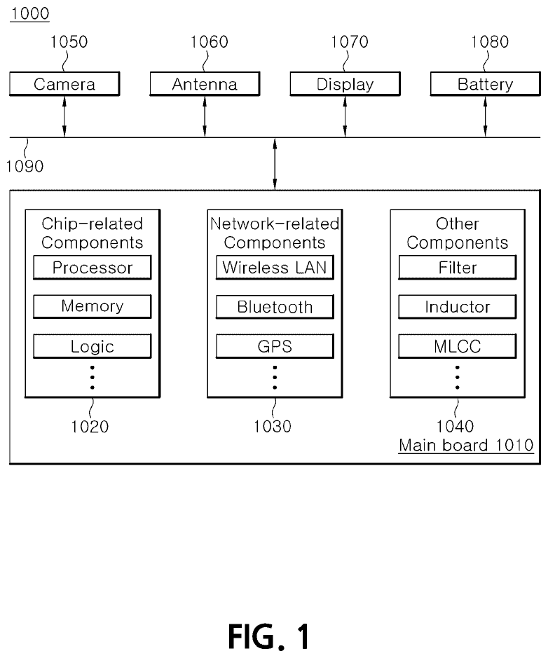

FIG. 1 is a schematic block diagram of an example of an electronic device system.

Referring to the drawings, an electronic device 1000 may accommodate a mainboard 1010. The mainboard 1010 may include chip-related components 1020, network-related components 1030, and other components 1040, physically or electrically connected thereto. Such components may be connected to other components to be described below to form various signal lines 1090.

The chip-related components 1020 may include a memory chip such as a volatile memory (for example, a dynamic random access memory (DRAM)), a non-volatile memory (for example, a read only memory (ROM)), or a flash memory, an application processor chip such as a central processor (for example, a central processing unit (CPU)), a graphics processor (for example, a graphics processing unit (GPU)), a digital signal processor, a cryptographic processor, a microprocessor, or a microcontroller, and a logic chip such as an analog-to-digital converter or an application-specific integrated circuit (ASIC). However, the chip-related components 1020 are not limited thereto, and may include other types of chip-related components. In addition, the chip-related components 1020 may be combined with each other. The chip-related components 1020 may be in the form of a package including the above-described chip or electronic component.

The network-related components 1030 may include protocols such as wireless fidelity (Wi-Fi) (Institute of Electrical And Electronics Engineers (IEEE) 802.11 family or the like), worldwide interoperability for microwave access (WiMAX) (IEEE 802.16 family or the like), IEEE 802.20, long term evolution (LTE), evolution data only (Ev-DO), high speed packet access+(HSPA+), high speed downlink packet access+(HSDPA+), high speed uplink packet access+(HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth®, 3G, 4G, and 5G protocols, and any other wireless and wired protocols, designated after the above-described protocols. However, the network-related components 1030 are not limited thereto, and may also include a variety of other wireless or wired standards or protocols. In addition, the network-related components 1030 may be combined with each other, together with the chip-related components 1020 described above.

The other components 1040 may include a high-frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, the other components 1040 are not limited thereto, and may also include passive components used for various other purposes, or the like. In addition, the other components 1040 may be combined with each other, together with the chip-related components 1020 or the network-related components 1030 described above.

Depending on a type of the electronic device 1000, the electronic device 1000 may include other components that may be or may not be physically or electrically connected to the mainboard 1010. The other components may include, for example, a camera module 1050, an antenna module 1060, a display 1070, a battery 1080, and the like. However, the other components are limited thereto, and may be an audio codec, a video codec, a power amplifier, a compass, an accelerometer, a gyroscope, a speaker, a mass storage unit (for example, a hard disk drive), a compact disk (CD), a digital versatile disk (DVD), or the like. In addition, the other components may also include other components used for various purposes depending on the type of electronic device 1000.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, and may be any other electronic device to process data.

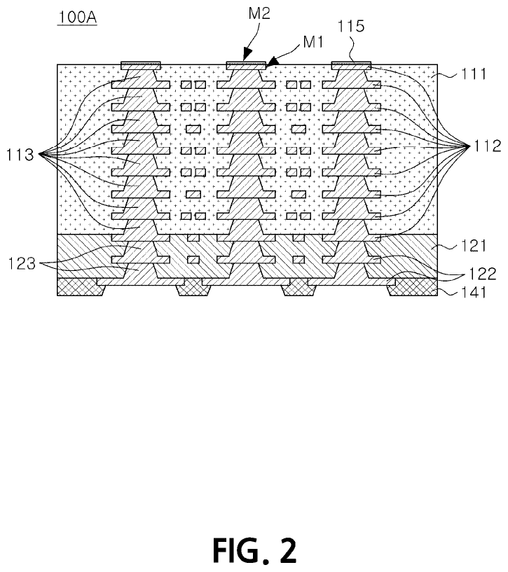

FIG. 2 is a schematic cross-sectional view of an example of a printed circuit board.

Referring to the drawings, a printed circuit board 100A according to an example may include a first insulating body 111, a plurality of first wiring layers 112 disposed on or in the first insulating body 111, and a plurality of first via layers 113 respectively disposed in the first insulating body 111, the plurality of first via layers 113 respectively connected to at least one first wiring layer 112, among the plurality of first wiring layers 112. An uppermost first wiring layer 112, among the plurality of first wiring layers 112, may include an embedded pattern M1 buried on an upper side of the first insulating body 111 such that at least a portion of an upper surface thereof is exposed from an upper surface of the first insulating body 111. A pattern layer 115 including a protruding pattern M2 may be disposed on the uppermost first wiring layer 112 including the embedded pattern M1. A thickness of the embedded pattern M1 may be less than a thickness of a wiring pattern included in at least one of remaining first wiring layers 112 excluding the uppermost first wiring layer 112. For example, a thickness of the uppermost first wiring layer 112 may be less than a thickness of each of the remaining first wiring layers 112.

As described, the printed circuit board 100A according to an example may have a coreless structure, and the uppermost first wiring layer 112 may include an embedded trace substrate (ETS)-type embedded pattern M1. Accordingly, a microcircuit may be easily implemented, and an overall thickness of the board may be reduced. In addition, a protruding pattern M2 may be formed and disposed on the embedded pattern M1. In this case, the embedded pattern M1 and the protruding pattern M2 may be directly connected to each other and/or in direct contact with each other. As a result, a partially protruding pad including the embedded pattern M1 and the protruding pattern M2 may be provided. Accordingly, a partially protruding pad having guaranteed size uniformity may be provided, thereby improving the mounting quality of a semiconductor chip or the like mounted on the pad. In addition, when the protruding pattern M2 is additionally formed, it may not be necessary to form a partially protruding pad by exposing a portion of the embedded pattern M1 using a process of performing plasma etching treatment on an uppermost side of the first insulating body 111. In the case of such plasma etching treatment, side effects such as crevice formation or the like may occur. The formation of the protruding pattern M2 may prevent the side effects, thereby ensuring the mounting reliability of a semiconductor chip or the like mounted on the pad. In addition, the uppermost first wiring layer 112, including the embedded pattern M1, may have a relatively small thickness, as compared to the remaining first wiring layers 112, thereby controlling an overall thickness of the pad and allowing the pad to be formed with desired dimensions.

A thickness of the pattern layer 115 including the protruding pattern M2 may be less than the thickness of the uppermost first wiring layer 112 including the embedded pattern M1. For example, the thickness of the partially protruding pad provided by the embedded pattern M1 and the protruding pattern M2, in direct contact with each other and/or directly connected to each other, may be substantially equal to the thickness of the wiring pattern included in at least one of the remaining first wiring layers 112. For example, a sum of the thickness of the outermost first wiring layer 112 and the thickness of the pattern layer 115 may be substantially equal to the thickness of each of the remaining first wiring layers 112. For example, the thickness of the embedded pattern M1 may be about 10 μm, the thickness of the protruding pattern M2 may be about 4 μm, and thus the pad provided through the embedded pattern M1 and the protruding pattern M2 may have a thickness of about 14 μm. In addition, thicknesses of wiring patterns included in the remaining first wiring layers 112 may be about 14 μm, and may be substantially equal to each other. For example, the thickness of the embedded pattern M1 may be about 65% to 75% of the thickness of the wiring pattern included in at least one of the remaining first wiring layers 112, and the thickness of the protruding pattern M2 may be about 25% to 35% of the thickness of the wiring pattern included in at least one of the remaining first wiring layers 112. Accordingly, the thickness of the partially protruding pad provided through the embedded pattern M1 and the protruding pattern M2 may be easily controlled within an appropriate range.

An upper surface of the uppermost first wiring layer 112 including the embedded pattern M1 and the upper surface of the first insulating body 111 may be substantially coplanar with each other. For example, the uppermost first wiring layer 112 may be formed as an ETS-type first wiring layer. Nevertheless, as in a process described below, the uppermost first wiring layer 112 may be protected by a barrier layer including nickel (Ni) or the like in a process of etching a copper foil, thereby preventing the occurrence of a recess step portion on an exposed surface of the uppermost first wiring layer 112. In this case, when forming the pattern layer 115 including the protruding pattern M2 on the uppermost first wiring layer 112 including the embedded pattern M1, a flat surface may be provided. Thus, the pattern layer 115 including the protruding pattern M2 may be formed with a finer pitch, and reliability may also be further improved.

The uppermost first wiring layer 112 including the embedded pattern M1 may not include a seed layer for plating. For example, the uppermost first wiring layer 112 may be formed as an ETS-type first wiring layer. Thus, as in the process described below, a metal layer of a carrier may be used as a seed layer, and the metal layer of the carrier may be removed. In addition, the pattern layer 115 including the protruding pattern M2 may not include a seed layer for plating. For example, the protruding pattern M2 may be formed using plating, based on the embedded pattern M1, as in the process described below. Thus, no seed layer may be present between the protruding pattern M2 and the embedded pattern M1. In this case, a process may be further simplified, and undercut or the like that may occur in a process of etching a seed layer may be prevented. However, the present disclosure is not limited thereto. A seed layer may be formed, as necessary, when the pattern layer 115 including the embedded pattern M1 is formed. Separately, the remaining first wiring layers 112 may include a seed layer. For example, the remaining first wiring layers 112 may be formed by forming a seed layer and performing a plating process based thereon.

A width of the embedded pattern M1 and a width of the protruding pattern M2 may be substantially equal to each other in cross-section. Accordingly, a side surface of each of the embedded pattern M1 and the protruding pattern M2 may have minimal or no step portion. In this case, a partially protruding pad having desired dimensions may be provided, and size uniformity may be further easily ensured. However, the present disclosure is not limited thereto. The width of the protruding pattern M2 in cross-section may be less than the width of the embedded pattern M1 in cross-section, as necessary.

Referring to the drawings, the printed circuit board 100A according to an example may further include a second insulating body 121 disposed on a lower side of the first insulating body 111, one or more second wiring layers 122 disposed on or in the second insulating body 121, and one or more second via layers 123 respectively disposed in the second insulating body 121, the one or more second via layers 123 respectively connected to at least one second wiring layer, among the one or more second wiring layers 122. A plurality of first wiring layers 112 and the one or more second wiring layers 122 may be electrically connected to each other. In this case, the second insulating body 121 may include an insulating material, different from an insulating material included in the first insulating body 111. For example, the second insulating body 121 may include an insulating material having an elastic modulus greater than that of the insulating material included in the first insulating body 111. In this case, it may be effective for warpage control. The second insulating body 121 may include an insulating material further including a glass fiber, for example, a prepreg, in addition to an insulating resin and an inorganic filler. In addition, the first insulating body 111 may include an insulating material including an insulating resin and an inorganic filler and not including a glass fiber, for example, an Ajinomoto build-up film (ABF). However, the materials are not limited thereto.

A connection via, included in each of the plurality of first via layers 113 and the one or more second via layers 123, may have a substantially tapered side surface in the same direction, in cross-section. For example, the connection via, included in each of the plurality of first via layers 113 and the one or more second via layers 123, may have a substantially tapered side surface having an upper end having a width, less than a width of a lower end thereof, in cross-section. As described above, the first wiring portions 111, 112, and 113 may be formed on the carrier using an ETS method, and the second wiring portions 121, 122, and 123 may be formed on the first wiring portions 111, 112, and 113 using a coreless method. Thus, the plurality of first via layers 113 and the one or more second via layers 123 may have such a tapered structure.

Referring to the drawings, the printed circuit board 100A according to an example may further include a passivation layer 141 disposed on a lower side of the second insulating body 121, the passivation layer 141 having a plurality of openings respectively exposing at least a portion of a lowermost second wiring layer 122, among the one or more second wiring layers 122. For example, the printed circuit board 100A according to an example may be a semiconductor package substrate or an interposer substrate, and may be mounted on a main board or other package substrates.

Hereinafter, components of the printed circuit board 100A according to an embodiment will be described in more detail with reference to the drawings.

Each of the first and second insulating bodies 111 and 121 may include an organic insulating material. The organic insulating material may include a thermosetting resin such as an epoxy resin, a thermoplastic resin such as polyimide, or an inorganic filler, an organic filler, and/or a glass fiber together with the above-described insulating resins. For example, the first insulating body 111 may include an insulating material including an insulating resin and an inorganic filler, for example, an ABF, but the present disclosure is not limited thereto. The first insulating body 111 may also include a photosensitive insulating material (PID) or the like. In addition, the second insulating body 121 may include an insulating material including an insulating resin, an inorganic filler, and a glass fiber, for example, a prepreg, but the present disclosure is not limited thereto. Each of the first and second insulating bodies 111 and 121 may include one or more insulating layers or a plurality of insulating layers, and the insulating layers may be integrated with each other such that boundaries therebetween are readily apparent or are not readily apparent. The first and second insulating bodies 111 and 121 may include a plurality of insulating layers from an overall perspective. In this case, the above-described partially protruding pad including the embedded pattern M1 and the protruding pattern M2 may be disposed on an outermost insulating layer, among the plurality of insulating layers, and the outermost insulating layer may include an insulating resin and an inorganic filler, but may not include a glass fiber. In addition, among the plurality of insulating layers, the outermost insulating layer and an outermost insulating layer that is opposite to the outermost insulating layer in a lamination direction may include an insulating resin, an inorganic filler, and a glass fiber.

Each of the first and second wiring layers 112 and 122 and the pattern layer 115 may include a metal. The metal may include copper (Cu), aluminum (Al), silver (Ag), tin (Sn), gold (Au), nickel (Ni), lead (Pb), titanium (Ti), and/or alloys thereof. For example, among the first and second wiring layers 112 and 122, the remaining first wiring layers excluding the uppermost first wiring layer 112 may include chemical copper, formed using electroless plating, as a seed layer, and may include electrolytic copper, formed using electroplating based thereon, as a pattern plating layer. However, the present disclosure is not limited thereto. Each of the remaining first wiring layers excluding the uppermost first wiring layer 112, among the first and second wiring layers 112 and 122, may include a titanium (Ti) layer and a copper (Cu) layer, formed using sputtering, as a seed layer. Each of the uppermost first wiring layer 112 and the pattern layer 115 may include electrolytic copper, formed using electroplating, as a pattern plating layer. For example, each of the embedded pattern M1 and the protruding pattern M2 may include electrolytic copper, formed using electroplating, as a pattern plating layer. Each of the first and second wiring layers 112 and 122 and the pattern layer 115 may perform various functions depending on a design thereof. For example, each of the first and second wiring layers 112 and 122 and the pattern layer 115 may include a signal transmission pattern, a power transmission pattern, a ground transmission pattern, or the like. The above-described patterns may have various pattern shapes such as a line, a trace, a plane, a pad, and a land. Each of the first and second wiring layers 112 and 122 may include one or more layers or a plurality of layers.

Each of the first and second via layers 113 and 123 may include a metal. The metal may include copper (Cu), aluminum (Al), silver (Ag), tin (Sn), gold (Au), nickel (Ni), lead (Pb), titanium (Ti), and/or alloys thereof. For example, the first and second via layers 113 and 123 may include chemical copper, formed using electroless plating, as a seed layer, and may include electrolytic copper, formed using electroplating based thereon, as a pattern plating layer. However, the present disclosure is not limited thereto. Each of the first and second via layers 113 and 123 may include a titanium (Ti) layer and a copper (Cu) layer, formed using sputtering, as a seed layer. Each of the first and second via layers 113 and 123 may perform various functions according to a design thereof. For example, each of the first and second via layers 113 and 123 may include a signal transmission via, a power transmission via, a ground transmission via, or the like. A connection via, included in each of the first and second via layers 113 and 123, may have a substantially tapered side surface having an upper end having a width less than a width of a lower end thereof in cross-section. A plurality of connection vias may be included in each of the first and second via layers 113 and 123. The connection via, included in each of the first and second via layers 113 and 123, may have a fill-plated via structure, but the present disclosure is not limited thereto, and may have a conformally plated via structure.

The passivation layer 141 may include an organic insulating material. The organic insulating material may include a thermosetting resin such as an epoxy resin, a thermoplastic resin such as polyimide, or an inorganic filler and/or an organic filler together with the above-described resins. For example, the organic insulating material may be an ABF, a photosensitive insulating material (PID), a solder resist (SR), or the like, but the present disclosure is not limited thereto. The passivation layer 141 may have a plurality of openings respectively exposing at least a portion of a lowermost second wiring layer 122. At least a portion of the lowermost second wiring layer 122, respectively exposed through the plurality of openings, may be of a solder mask defined (SMD) type and/or a non-solder mask defined (NSMD) type.

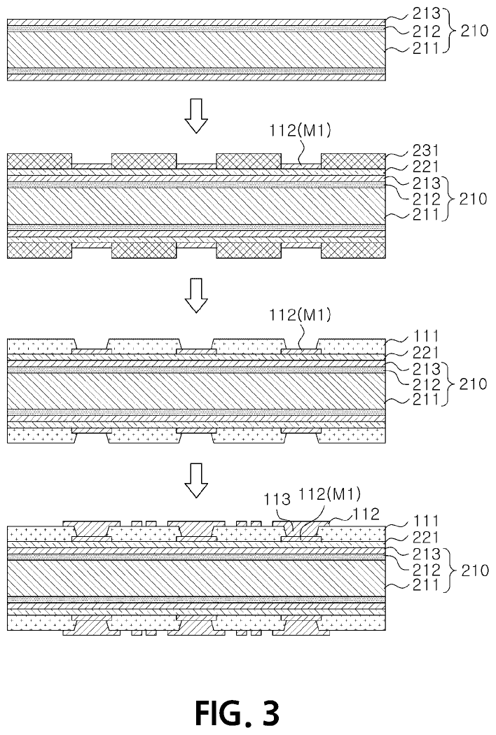

FIGS. 3 to 5 are schematic process cross-sectional views of an example of manufacturing the printed circuit board of FIG. 2.

Referring to FIG. 3, first, a carrier 210 may be prepared. The carrier 210 may include a core material 211 and a plurality of metal layers 212 and 213 disposed on both surfaces of the core material 211. The core material 211 may be an organic insulating material having excellent rigidity, including an insulating resin, an inorganic filler, and a glass fiber, but the present disclosure is not limited thereto, and may also be an inorganic insulating material such as glass, ceramic, silicon, or the like. Each of the plurality of metal layers 212 and 213 may include copper (Cu), but the present disclosure is not limited thereto and may also include other metals. Subsequently, a barrier layer 221 may be formed on the metal layer 213. The barrier layer 221 may include nickel (Ni), but the present disclosure is not limited thereto and may also include another metal different from that of the metal layer 213. Subsequently, a first wiring layer 112 including an embedded pattern M1 may be formed on the barrier layer 221. For example, a dry film 231 may be formed on the barrier layer 221, and may be patterned using a photolithography process, and electroplating or the like may be performed on a patterned opening of the dry film 231 to form an ETS pattern with the M1 layer. Subsequently, the dry film 231 may be removed using a peeling process, and a first insulating layer included in a first insulating body 111 may be formed using a lamination process. In addition, a via hole, exposing at least a portion of the embedded pattern M1, may be formed in the first insulating layer included the first insulating body 111 using laser processing. Subsequently, a first wiring layer 112 may be further formed on the first insulating layer included in the first insulating body 111 using a circuit forming process such as a semi additive process (SAP) or the like, and a first via layer 113 may be formed in the via hole.

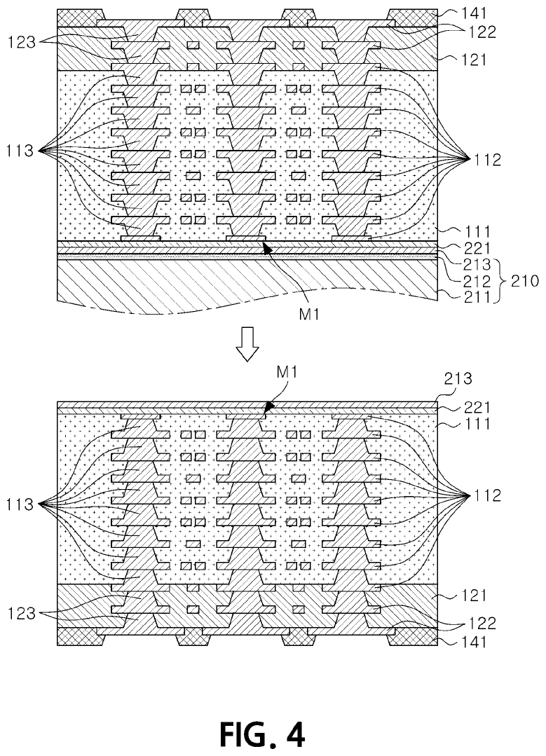

Referring to FIG. 4, subsequently, a build-up process or a coreless process may be used to repeatedly perform the above-described lamination process, via hole processing, and circuit formation process to form the first insulating body 111, a plurality of first wiring layers 112, and a plurality of first via layers 113. In addition, a second insulating body 121, one or more second wiring layers 122 and one or more second via layers 123 may be formed. In addition, a passivation layer 141 may be formed using a coating process or a lamination process. Subsequently, a laminate formed on the carrier 210 may be separated. For example, a plurality of metal layers 212 and 213 of the carrier 210 may be separated from each other. In this case, the metal layer 213 and the barrier layer 221 may remain in the laminate. A laminate may be formed on each of both surfaces of the carrier 210, and thus a plurality of laminates may be obtained after separation. The laminate may be vertically inverted, as necessary.

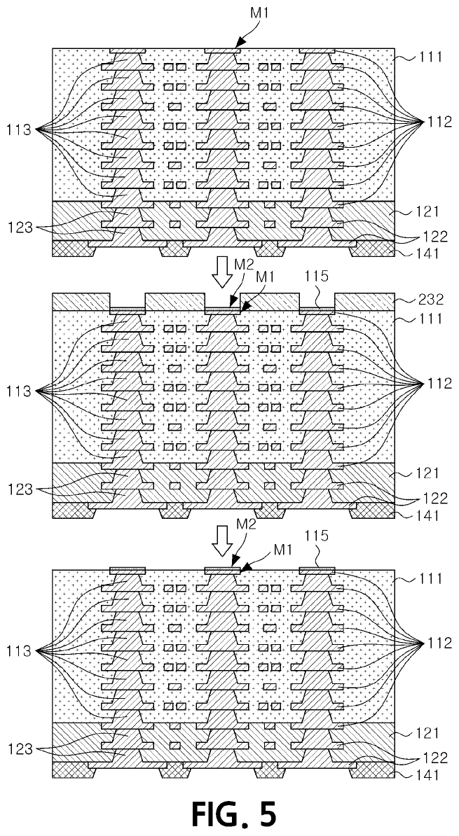

Referring to FIG. 5, subsequently, the metal layer 213 and the barrier layer 221 may be sequentially removed. The metal layer 213 and the barrier layer 221 may be removed by respective etching processes, and the barrier layer 221 may not be etched during the etching process of the metal layer 213. Accordingly, an outermost first wiring layer 112, for example, an uppermost first wiring layer 112 including the embedded pattern M1 may be protected. Accordingly, an upper surface of the uppermost first wiring layer 112 including the embedded pattern M1 may be substantially coplanar with an upper surface of the first insulating body 111. Subsequently, a protruding pattern M2 may be directly formed on the embedded pattern M1, thereby forming a partially protruding pad. For example, a dry film 232 may be formed on the first insulating body 111, an opening for exposing the embedded pattern M1 may be formed using patterning the dry film 232, and the opening may be filled by a desired thickness by electroplating to form a pattern layer 115 including the protruding pattern M2. For example, the pattern layer 115 including the protruding pattern M2 may be formed using an SAP process. Subsequently, the dry film 232 may be removed using a peeling process.

The above-described printed circuit board 100A according to an example may be manufactured through a series of processes. Other contents may be substantially the same as those described with reference to the above-described printed circuit board 100A according to an example.

As used herein, the terms “cover,” “to cover,” and “covering” may include entirely covering as well as at least partially covering, and may include directly covering as well as indirectly covering. In addition, the terms “fill,” to fill,” and “filling” may include not only entirely filling, but also approximately filling, for example, may include a case in which some voids, pores or the like are present. In addition, the terms “surround,” “to surround,” and “surrounding” may include not only entirely surrounding but also approximately surrounding. In addition, exposing may include not only entirely exposing but also exposing at least a portion of a structure, and exposure may mean exposing a component from another component in which the component is buried. For example, an opening, exposing a pad, may be exposing the pad from a resist layer, and a surface treatment layer may be further disposed on the exposed pad.

As used herein, a process error or a positional deviation occurring in a manufacturing process, an error in measurement, and the like may be included. For example, “substantially coplanar” may include not only “completely coplanar,” but also “approximately coplanar.” In addition, “being disposed on substantially the same level” may include not only “being disposed on completely the same level,” but also “being disposed on approximately the same level.” In addition, “having a substantially specific shape” may include not only “having a completely specific shape,” but also “having an approximately specific shape.” In addition, the same insulating material may mean not only the exact same insulating material, but also the same type of insulating material. Thus, compositions of insulating materials may be substantially the same, but specific composition ratios thereof may slightly vary.

As used herein, “in cross-section” may refer to a cross-sectional shape of an object when the object is vertically cut, or a cross-sectional shape of the object when the object is viewed in a side-view. In addition, a shape on a plane may be a shape of the object when the object is horizontally cut, or a planar shape of the object when the object is viewed in a top-view or a bottom-view.

As used herein, an upper side, an upper portion, the upper surface, or the like is used to refer to a direction toward a surface on which an electronic component is mountable based on a cross-section of a drawing for ease, and a lower side, a lower portion, a lower surface, or the like is used to refer to an opposite direction thereof. However, the above-described directions are defined for ease of description. Thus, it should be understood that the scope of the claims is not particularly limited by the above-described directions, and the concepts of “upper” and “lower” may change at any time.

As used herein, the term “connected” may not only refer to “directly connected” but also include “indirectly connected” by means of an adhesive layer, or the like. The term “electrically connected” may include both of a case in which components are “physically connected” and a case in which components are “not physically connected.” In addition, the terms “first,” “second,” and the like may be used to distinguish a component from another component, and may not limit a sequence and/or an importance, or others, in relation to the components. In some cases, a first component may be referred to as a second component, and similarly, a second component may be referred to as a first component without departing from the scope of the example embodiments.

As used herein, a thickness, a width, a length, a depth, a line width, a space, a pitch, and the like may be measured using a scanning microscope or an optical microscope based on a cross-section obtained by polishing or cutting a printed circuit board. The cross-section may be a vertical cross-section or a horizontal cross-section, and each value may be measured based on the required cross-section. For example, a width of an upper end and/or lower end of a via may be measured in cross-section taken along a central axis of the via. In this case, when a component does not have a predetermined value, the value may be determined as an average value of values measured at arbitrary five points.

As used herein, the term “an example” does not mean the same example embodiment, and is provided to emphasize different unique features. However, the examples presented above do not preclude implementation in combination with features of other examples. For example, a context described in a specific example may be used in other examples, even if it is not described in the other example examples, unless it is described contrary to or inconsistent with the context in the other examples.

The terms used herein describe particular examples only, and the present disclosure is not limited thereby. As used herein, singular forms “a,” “an,” and “the” are intended to include the plural forms as well, unless the context clearly indicates otherwise.

While example embodiments have been shown and described above, it will be apparent to those skilled in the art that modifications and variations could be made without departing from the scope of the present disclosure as defined by the appended claims.

What is claimed is:

1. A printed circuit board comprising:
a first insulating body;
a plurality of first wiring layers respectively disposed on or in the first insulating body; and
a plurality of first via layers respectively disposed in the first insulating body, the plurality of first via layers respectively connected to at least one first wiring layer, among the plurality of first wiring layers,
wherein an uppermost first wiring layer, among the plurality of first wiring layers, includes an embedded pattern buried in an upper side of the first insulating body such that at least a portion of an upper surface thereof is exposed from an upper surface of the first insulating body,
a protruding pattern is disposed on the embedded pattern, and
a thickness of the embedded pattern is less than a thickness of a wiring pattern included in at least one of remaining first wiring layers excluding the uppermost first wiring layer.

2. The printed circuit board of claim 1, wherein a thickness of the protruding pattern is less than the thickness of the embedded pattern.

3. The printed circuit board of claim 2, wherein the embedded pattern and the protruding pattern are directly connected to each other.

4. The printed circuit board of claim 3, wherein
the embedded pattern and the protruding pattern are directly connected to each other such that a pad is provided, and
a thickness of the pad is substantially equal to the thickness of the wiring pattern included in at least one of the remaining first wiring layers excluding the uppermost first wiring layer.

5. The printed circuit board of claim 3, wherein
the thickness of the embedded pattern is 65% to 75% of the thickness of the wiring pattern included in at least one of the remaining first wiring layers excluding the uppermost first wiring layer, and
the thickness of the protruding pattern is 25% to 35% of the thickness of the wiring pattern included in at least one of the remaining first wiring layers excluding the uppermost first wiring layer.

6. The printed circuit board of claim 1, wherein upper surfaces of the embedded pattern and the first insulating body are substantially coplanar with each other.

7. The printed circuit board of claim 1, wherein the protruding pattern has a width substantially equal to a width of the embedded pattern, in cross-section.

8. The printed circuit board of claim 1, wherein
each of the remaining first wiring layers excluding the uppermost first wiring layer includes a seed layer, and
each of the embedded pattern and the protruding pattern is formed without a seed layer.

9. The printed circuit board of claim 1, further comprising:
a second insulating body disposed on a lower side of the first insulating body;
one or more second wiring layers respectively disposed on or in the second insulating body; and
one or more second via layers respectively disposed in the second insulating body, the one or more second via layers respectively connected to at least one second wiring layer, among the one or more second wiring layers,
wherein the plurality of first wiring layers and the one or more second wiring layers are electrically connected to each other, and
the second insulating body includes an insulating material, different from an insulating material of the first insulating body.

10. The printed circuit board of claim 9, wherein the second insulating body includes an insulating material having an elastic modulus greater than that of the insulating material included in the first insulating body.

11. The printed circuit board of claim 9, wherein a connection via, included in each of the plurality of first and second via layers, has a substantially tapered side surface, the tapered side surface having an upper end with a width, less than a width of a lower end thereof, in cross-section.

12. The printed circuit board of claim 8, further comprising:
a passivation layer disposed on a lower side of a second insulating body, the passivation layer having a plurality of openings exposing at least a portion of a lowermost third wiring layer, among one or more third wiring layers.

13. A printed circuit board comprising:
a plurality of insulating layers;
a plurality of wiring layers respectively disposed on or in the plurality of insulating layers;
a plurality of via layers respectively disposed in the plurality of insulating layers, the plurality of via layers respectively connected to at least one insulating layer, among the plurality of insulating layers; and
a pattern layer disposed on an outermost wiring layer, among the plurality of wiring layers, the pattern layer in direct contact with the outermost wiring layer,
wherein the outermost wiring layer is buried in an outermost insulating layer, among the plurality of insulating layers, such that one surface thereof is exposed from one surface of the outermost insulating layer, and
a thickness of the outermost wiring layer is less than a thickness of each of the remaining wiring layers, among the plurality of wiring layers.

14. The printed circuit board of claim 13, wherein a thickness of the pattern layer is less than the thickness of the outermost wiring layer.

15. The printed circuit board of claim 13, wherein the one surface of the outermost wiring layer is substantially coplanar with the one surface of the outermost insulating layer.

16. The printed circuit board of claim 13, wherein a connection via, included in each of the plurality of via layers, has a substantially tapered side surface extending in a same direction in cross-section.

17. A method of manufacturing the printed circuit board of claim 1, comprising:
forming an embedded pattern in an upper side of a first insulating body such that at least a portion of an upper surface of the embedded pattern is exposed from an upper surface of the first insulating body;
forming a protruding pattern on the embedded pattern by electroplating, without performing plasma etching on the upper surface of the first insulating body;
wherein the embedded pattern and the protruding pattern are directly connected to each other to form a protruding pad, and
a combined thickness of the embedded pattern and the protruding pattern is substantially equal to a thickness of a wiring pattern included in at least one of the first wiring layers other than the uppermost first wiring layer.

18. The method of claim 17, wherein the protruding pattern is formed to have a thickness less than a thickness of the embedded pattern.

19. The method of claim 18, wherein the protruding pattern is directly formed on the embedded pattern such that the embedded pattern and the protruding pattern are directly connected to each other.

20. The method of claim 19, wherein the embedded pattern is formed to have a thickness that is 65% to 75% of a thickness of a wiring pattern included in at least one of the first wiring layers other than the uppermost first wiring layer, and the protruding pattern is formed to have a thickness that is 25% to 35% of the thickness of the wiring pattern.
